(19) United States
(12) Patent Application Publication
(10) Pub. No.: US 2020/0203287 A1
(43) Pub. Date: Jun. 25, 2020

(54) DEVICE COMPRISING COMPARTMENTAL SHIELDING WITH IMPROVED HEAT DISSIPATION AND ROUTING

(71) Applicant: QUALCOMM Incorporated, San Diego, CA (US)

(72) Inventors: Anna Katharina KREFFT, Munich (DE); Markus VALTERE, Munich (DE)

(21) Appl. No.: 16/228,497

(22) Filed: Dec. 20, 2018

(51) Int. Cl. H01L 23/552; H01L 23/31; H01L 25/16; H01L 23/498; H01L 23/367; H01L 21/56; H01L 21/48

(52) U.S. Cl. CPC H01L 23/552; H01L 23/3128; H01L 25/16; H01L 21/4814; H01L 23/3675; H01L 21/56; H01L 23/49822

(57) ABSTRACT

A device that includes a substrate, a first component coupled to the substrate, a second component coupled to the substrate, an encapsulation layer formed over the substrate such that the encapsulation layer encapsulates the first component and the second component, and a shielding layer formed over a first surface of the encapsulation layer. The shielding layer includes a first portion formed in a first cavity of the encapsulation layer. The first cavity is located between the first component and the second component. The first portion of the shielding layer provides a compartmental electromagnetic (EM) shield between the first component and the second component.

### BACKGROUND

### Field

Various features relate to devices that includes compartmental shielding, but more specifically to devices that include compartmental shielding with improved heat dissipation and routing.

### Background

FIG. 1 illustrates an integrated device 100 that includes a substrate 102 and a die 104. The die 104 is coupled to a first surface of the substrate 102 through a plurality of solder interconnects 140, which may include bumps and pillars.

The substrate 102 includes a plurality of dielectric layers 120, a plurality of interconnects 122, and a plurality of surface interconnects 123. Each layer of the dielectric layers 120 includes a patterned metal layer and vias. The substrate 102 includes a first solder resist layer 124, a second solder resist layer 126, and a plurality of solder interconnects 130. A capacitor 150 is mounted over the first surface of the substrate 102. An encapsulation layer 160 encapsulates the die 104 and the capacitor 150. The die 104 and the capacitor 150 may each generate their own respective electromagnetic (EM) field. In addition, the die 104 and the capacitor 150 may be subject to external EM fields. All of these EM fields may impact the performance of the die 104 and/or the capacitor 150.

The integrated device 100 is a relatively small device, with components that are located very close to each other. As such, it can be challenging and very difficult to create an electromagnetic shield that can isolate components of the integrated device 100 from the EM fields. These electromagnetic shields are bulky and take up a lot of real estate, making them not practical nor useful for small devices since space is very limited for small devices. In addition, the size of the electromagnetic shield and the process of implementing an electromagnetic shield requires a lot of spacing between the die 104 and the capacitor 150, which creates unnecessarily bulky integrated devices.

Therefore, there is a need for providing a device that includes electromagnetic shielding for components of the devices. Ideally, the electromagnetic shielding may be implemented in small devices and in small spaces, while also providing various functionalities and capabilities, such as providing improved heat dissipation and improved interconnect routing for the device.

### SUMMARY

Various features relate to devices that includes compartmental shielding, but more specifically to devices that include compartmental shielding with improved heat dissipation and routing.

One example provides a device that includes a substrate, a first component coupled to the substrate, a second component coupled to the substrate, an encapsulation layer formed over the substrate such that the encapsulation layer encapsulates the first component and the second component, and a shielding layer formed over a first surface of the encapsulation layer. The shielding layer includes a first portion formed in a first cavity of the encapsulation layer. The first cavity is located between the first component and the second component. The first portion of the shielding layer provides a compartmental electromagnetic (EM) shield between the first component and the second component.

Another example provides a device that includes a substrate, a first component coupled to the substrate, a second component coupled to the substrate, means for encapsulating formed over the substrate such that the means for encapsulating encapsulates the first component and the second component, and means for shielding formed over a first surface of the means for encapsulating. The means for shielding includes a first portion formed in a first cavity of the means for encapsulating. The first cavity is located between the first component and the second component. The first portion of the means for shielding provides means for compartmental electromagnetic (EM) shielding between the first component and the second component.

Another example provides a method for fabricating a device having shielding. The method provides a device that includes a substrate; a first component coupled to the substrate; a second component coupled to the substrate; and an encapsulation layer formed over the substrate such that the encapsulation layer encapsulates the first component and the second component. The method forms a plurality of cavities in the encapsulation layer, including forming a first cavity in the encapsulation layer between the first component and the second component. The method forms a shielding layer over a first surface of the encapsulation layer, including forming a first portion of the shielding layer in the first cavity of the encapsulation layer, wherein the first portion of the shielding layer provides a compartmental electromagnetic (EM) shield between the first component and the second component.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of an integrated device that includes a die, a substrate and a passive component.

FIG. 2 illustrates a profile view of a device that includes a die, a substrate, a passive component, an encapsulation layer, and an electromagnetic shield.

FIG. 3 illustrates a plan view of a device that includes a die, a substrate, a passive component, an encapsulation layer, and an electromagnetic shield.

FIG. 4 illustrates a profile view of a device that includes a die, a substrate, a passive component, an encapsulation layer, and an electromagnetic shield.

FIG. 5 illustrates a profile view of a device that includes a die, a substrate, a passive component, an encapsulation layer, and an electromagnetic shield.

FIG. 6 (comprising FIGS. 6A-6B) illustrates an exemplary sequence for fabricating a device that includes a die, a substrate, a passive component, an encapsulation layer, and an electromagnetic shield.

FIG. 7 illustrates an exemplary flow diagram of a method for fabricating a device that includes a die, a substrate, a passive component, an encapsulation layer, and an electromagnetic shield.

FIG. 8 illustrates a profile view of a device that includes a die, a substrate, a passive component, an encapsulation layer, and an electromagnetic shield.

FIG. 9 illustrates a profile view of a device that includes a die, a substrate, a passive component, an encapsulation layer, and an electromagnetic shield.

FIG. 10 illustrates a profile view of a device that includes a die, a substrate, a passive component, an encapsulation layer, and an electromagnetic shield.

FIG. 11 (comprising FIGS. 11A-11B) illustrates an exemplary sequence for fabricating a device that includes a die, a substrate, a surface mounted passive component, an encapsulation layer, and an electromagnetic shield.

FIG. 12 illustrates various electronic devices that may integrate a die, an integrated device, an integrated passive device (IPD), a passive component, a package, and/or a device package described herein.

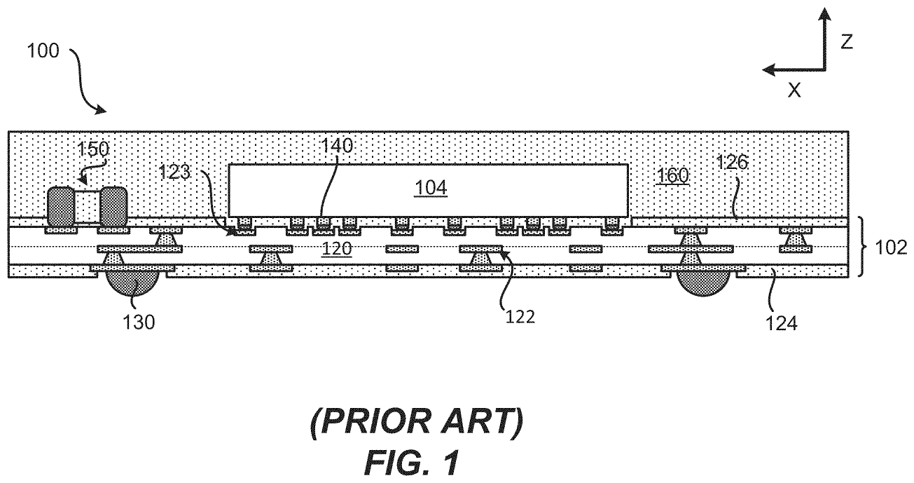

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device that includes a substrate, a first component coupled to the substrate, a second component coupled to the substrate, an encapsulation layer formed over the substrate such that the encapsulation layer encapsulates the first component and the second component, and a shielding layer formed over the encapsulation layer. The shielding layer includes a first portion formed in a first cavity of the encapsulation layer. The first cavity is located laterally between the first component and the second component. The first portion of the shielding layer provides a compartmental electromagnetic (EM) shield between the first component and the second component. In some implementations, different portions of the shielding layer may be configured (i) as an interconnect to provide an electrical path between the first component and the substrate, (ii) as an interconnect to provide an electrical path between the first component and the second component, as an interconnect to provide an electrical path between the first component and a component embedded in the substrate, (iii) as a heat dissipating structure to provide heat dissipation of the first component and/or the second component, (iv) as an interconnect to a ground layer, and/or (v) as a conformal EM shield for the first component and/or the second component. In some implementations, the device may be an integrated device or a system in package (SiP). In some implementations, the first component may be a radio frequency (RF) component, a die, or a passive component (e.g., capacitor).

### Exemplary Device Comprising Compartmental Electromagnetic (EM) Shield

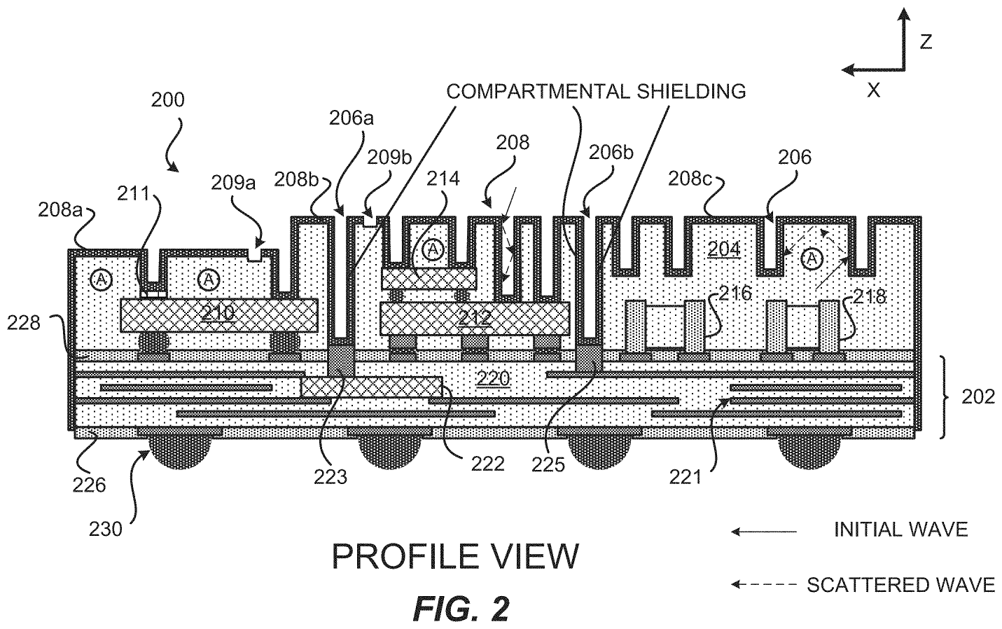

FIG. 2 illustrates a profile view of a device 200 that includes a substrate 202, a first component 210, a second component 212, a third component 214, a fourth component 216, a fifth component 218, a sixth component 222, an encapsulation layer 204, and a shielding layer 208. Some or all portions of the shielding layer 208 may be configured as an electromagnetic (EM) shield. In some implementations, the device 200 may be an integrated device or a system in package (SiP).

The shielding layer 208 is formed over the encapsulation layer 204 and the substrate 202. The shielding layer 208 may include one or more portions that are configured to be coupled to ground. The shielding layer 208 may be configured to provide compartmental EM shielding and/or conformal EM shielding for the device 200. The compartmental EM shielding may include internal walls in the encapsulation layer 204. The shielding layer 208 may be implemented in small areas and small footprints, enabling a tightly packaged device to have effective and robust EM shielding, without sacrificing the size of the device.

Moreover, as will be further described below, one or more portions of the shielding layer 208 may be configured to provide (i) heat dissipating capabilities for components of the device 200, (ii) connections between components and the substrate, (iii) connections between components, and/or (iv) surfaces for scattering EM waves. Thus, the shielding layer 208 is a part of the device 200 that may provide multi-function capabilities.

FIG. 2 illustrates that the substrate 202 includes one or more dielectric layers 220, a plurality of interconnects 221, an interconnect 223, an interconnect 225, a first solder resist layer 226, and a second solder resist layer 228. The interconnect 223 and the interconnect 225 may be part of the plurality of interconnects 221. The plurality of interconnects 221 may be redistribution layer interconnects. Examples of the plurality of interconnects 221 include a trace, a pad and/or a via. The sixth component 222 is embedded in the substrate 202. In some implementations, the sixth component 222 may be an electronic component, a radio frequency (RF) component, a die, or a passive component.

The first component 210, the second component 212, the fourth component 216 and the fifth component 218 are coupled to the substrate 202. The third component 214 is coupled to the second component 212. For example, the third component 214 may be stacked over the second component 212. In some implementations, each of the above components (e.g., 210, 212, 214, 216, 218) may be an electronic component, a RF component, a die, or a passive component. For example, the first component 210 may be an RF component, the second component 212 may be a die (e.g., processor die), the third component 214 may be a die (e.g., memory die), the fourth component 216 may be a capacitor, and the fifth component 218 may be capacitor (e.g., multi-layer ceramic capacitor (MLCC)). The arrangement, configuration and types of components in FIG. 2 are merely exemplary. Different implementations may have different numbers of components, with different arrangements, different configurations and different types of components.

The encapsulation layer 204 encapsulates the first component 210, the second component 212, the third component 214, the fourth component 216 and the fifth component 218. The encapsulation layer 204 includes a plurality of cavities 206 (e.g., first cavity, second cavity, third cavity, etc.). The plurality of cavities 206 is formed in the encapsulation layer 204 and may travel through the encapsulation layer 204 at various depths. The plurality of cavities 206 has walls that are approximately vertical (e.g., approximately 90 degrees to surface of substrate or surface of component, approximately perpendicular to surface of substrate or surface of component). However, in some implementations, the plurality of cavities 206 may have walls that are non-vertical (e.g., slanted, diagonal). For example, the plurality of cavities 206 may be tapered. In some implementations, the diameter, width or opening of each cavity (without any shielding layer) may be approximately 10 micrometers (μm) or greater (e.g., minimum diameter or minimum width of approximately 10 micrometers (μm)).

The spacing between components in the encapsulation layer 204 may vary. In some implementations, a minimum spacing between two neighboring components is approximately 75 micrometers (μm). In some implementations, a minimum spacing between two neighboring components is approximately 50 micrometers (μm). Different implementations may use different minimum spacing between two neighboring components. The present disclosure provides a compartmental shield that can be formed between two neighboring components such that a spacing between the compartmental shield (e.g., formed from a portion of the shielding layer 208) and a component (e.g., 210, 212, 216) is less than 75 micrometers (μm). In some implementations, a spacing between a compartment shield and a component is approximately 40 micrometers (μm) or less. In some implementations, the above mentioned spacing is possible because of the process for forming a shielding layer described in the disclosure.

The plurality of cavities 206 may be formed using various processes. In some implementations, the plurality of cavities 206 may be formed using a laser process (e.g. laser ablation). In some implementations, the plurality of cavities 206 may be formed using a photo etching process. Different implementations may use different materials for the encapsulation layer 204. For example, the encapsulation layer 204 may include a mold, a resin and/or an epoxy.

FIG. 2 further illustrates the shielding layer 208 is formed over the encapsulation layer 204, including being formed (i) over a first surface of the encapsulation layer 204, (ii) in one or more cavities of the plurality of cavities 206 and (iii) over a side portion of the encapsulation layer 204. In some implementations, the first surface of the encapsulation layer 204 may be a surface (e.g., horizontal surface) of the encapsulation layer that faces away from the substrate. The first surface of the encapsulation layer 204 may be approximately parallel to a planar surface of the substrate 202. In some implementations, a portion of the shielding layer 208 that travel vertically along a cavity and horizontally along the first surface of the encapsulation layer may be a contiguous portion of the shielding layer 208.

The shielding layer 208 may also be formed over a side portion of the substrate 202. The shielding layer 208 may be a patterned shielding layer that follows the contours of some or all portions of the encapsulation layer 204. Some or all portions of the shielding layer 208 may be configured to reduce electromagnetic fields and/or waves in space by providing a barrier. Some or all portions of the shielding layer 208 may be configured to couple to ground. Some or all portions of the shielding layer 208 may be configured to isolate one or more components from their surroundings, thus reducing the impact of electromagnetic fields and/or waves. In some implementations, the shielding layer 208 may be made of one or more materials with conductive and/or magnetic properties. The shielding layer 208 may include one or more layers.

Different implementations may use different materials for the shielding layer 208. The shielding layer 208 may include one or more layers of the same material or different materials. In some implementations, the shielding layer 208 may include a metal such as copper (Cu), silver (Ag), gold (Au), and/or Aluminum (Al). In some implementations, the shielding layer 208 may include a non-metal that is thermally and/or electrically conductive, such as diamond like carbon and/or conductive polymers. Examples of conductive polymers include (poly(fluorene)s, polyphenylenes, polypyrenes, polyazulenes, polynaphthalenes, poly(pyrrole)s, polycarbazoles, polyindoles, polyazepines, polyanilines, poly(thiophene)s, poly(3,4-ethylenedioxythiophene), poly(p-phenylene sulfide), Poly(p-phenylene vinylene), poly(acetylene)s). In some implementations, the shielding layer 208 may include a combination of metal material(s) and/or non-metal material(s).

As mentioned above, the shielding layer 208 may provide multi-function capabilities. For example, one or more portions of the shielding layer 208 may be configured to provide (i) EM shielding for one or more components, (ii) heat dissipating capabilities for components of the device 200, (iii) connections between components and the substrate, and/or (iv) surfaces and space for scattering EM waves.

### Structure for Electromagnetic (EM) Shielding

As mentioned above, electromagnetic (EM) shielding can include conformal shielding and compartmental shielding. The shielding layer 208 may be a means for shielding (e.g., means for EM shielding). One or more portions of the shielding layer 208 may be configured to be coupled to ground. In some implementations, conformal shielding provides a way for the components of the device to be isolated from external electromagnetic fields and/or waves. Some or all portions of the shielding layer 208 may be configured to provide conformal shielding (e.g., means for conformal shielding, means for conformal EM shielding). For example, portions of the shielding layer 208 that is outside of the device 200 may be configured to provide conformal shielding. Examples of these portions include portions of the shielding layer 208 that are located over the side of the substrate 202, over the side (e.g., vertical surface, lateral surface) of the encapsulation layer 204, and/or over the horizontal surface of the encapsulation layer 204. A first portion 208a of the shielding layer 208, a second portion 208b of the shielding layer 208, and a third portion 208c of the shielding layer 208 are examples of portions of the shielding layer 208 that may be configured to provide conformal shielding.

In some implementations, compartmental shielding provides a way for components of the device to be isolated from each other. As such, compartmental shielding reduces the effect of electromagnetic fields and/or waves from one component to another component of the device. Some portions of the shielding layer 208 may be configured to provide compartmental shielding. For example, certain cavities of the encapsulation layer 204 may be located between components encapsulated by the encapsulation layer 204 and these cavities include portions of the shielding layer 208 that are configured as compartmental EM shielding (e.g., means for compartmental shielding, means for compartmental EM shielding).

FIG. 2 illustrates a first cavity 206a located between the first component 210 and a second component 212. The first cavity 206a is filled (e.g., partially filled) with the shielding layer 208. In particular, the second portion 208b of the shielding layer 208 is located (e.g., located laterally) between the first component 210 and the second component 212 The second portion 208b of the shielding layer 208 isolates the first component 210 from the second component 212, and vice versa. In addition to having the shielding layer 208 between the first component 210 and the second component 212, there is also a gap (e.g., air gap) between the first component 210 and the second component 212. It is noted that the second portion 208b of the shielding layer 208 may also provide conformal EM shielding.

FIG. 2 also illustrates a second cavity 206b that is filled (e.g., partially filled) with the shielding layer 208. In particular, the third portion 208c of the shielding layer 208 is located between the second component 212 and the fourth component 216 The third portion 208c of the shielding layer 208 isolates the second component 212 from the fourth component 216, and vice versa. In addition to having the shielding layer 208 between the second component 212 and the fourth component 216, there is also a gap (e.g., air gap) between the second component 212 and the fourth component 216. It is noted that the third portion 208c of the shielding layer 208 may also provide conformal EM shielding.

### Shielding Layer Structure for Heat Dissipation

In some implementations, some or all portions of the shielding layer 208 may be configured to provide heat dissipation for components encapsulated by the encapsulation layer 204. Thus, in some implementations, portions of the shielding layer 208 may be a means for heat dissipation.

FIG. 2 illustrates portions of the first portion 208a of the shielding layer 208 is coupled to a heat sink 211. The heat sink 211 is coupled to the first component 210 (e.g., coupled to backside of the first component 210. FIG. 2 also illustrates that the second portion 208b of the shielding layer 208 is coupled to the first component 210. In some implementations, heat that is generated by the first component 210 may dissipate through (i) the heat sink 211 and the first portion 208a of the shielding layer 208 and (ii) the second portion 208b of the shielding layer 208. The shielding layer 208 may be coupled (e.g., directly coupled, indirectly coupled) to other components of the device 200 to provide heat dissipation for one or more components.

The encapsulation layer 204 is not a good thermal conductor of heat. Thus, when a component is encapsulated by the encapsulation layer 204, heat generated by the component does not dissipate from the component very well. By providing a path for heat from the component to dissipate through the use of the shielding layer 208, which has a much higher thermal conductivity value, more heat can be dissipated from the component.

Shielding Layer Structure for Connection with Substrate

In some implementations, some or all portions of the shielding layer 208 may be configured to provide connections (e.g., electrical connections) between one or more components and/or the substrate 202. Thus, in some implementations, portions of the shielding layer 208 may be a means for electrical connection. One or more portions of the shielding layer 208 may be coupled to one or more components and/or the substrate 202. The one or more portions of the shielding layer 208 may be separated from other portions of the shielding layer 208 that are configured to couple to ground. Thus, in some implementations, one or more portions of the shielding layer 208 may be coupled to ground, while one or more other portions of the shielding layer 208 may be configured to carry one or more electrical signals. The one or more other portions of the shielding layer 208 may be configured as interconnect(s) to the substrate 202, as interconnect(s) to embedded component(s) in the substrate 202, and/or as interconnect(s) to components mounted on the substrate 202.

FIG. 2 illustrates the second portion 208b of the shielding layer 208 is coupled to the first component 210 and the substrate 202. The second portion of the shielding layer 208 is separated from other portions of the shielding layer 208 through breaks 209a and 209b. The second portion 208b of the shielding layer 208 is coupled to the first component 210 and the interconnect 223 of the substrate 202. The interconnect 223 is coupled to the sixth component 222. Thus, the second portion 208b of the shielding layer 208 provides an interconnect between the first component 210 and the sixth component 222, such that an electrical signal may travel between the first component 210 and the sixth component 222. Different implementations may provide different portions of the shielding layer 208 such that different components may be coupled to the substrate 202 and/or components embedded in the substrate 202. In some implementations, one or more portions of the shielding layer 208 may be configured to provide one or more electrical signals between components over the substrate 202. For example, one or more portions of the shielding layer 208 may be configured as an interconnect(s) between the first component 210 and the third component 214.

Utilizing the shielding layer 208 for routing and providing connections between the substrate 202 and components may enable the substrate 202 to be thinner since space in the substrate 202 that would have been previously needed is no longer needed when portions of the shielding layer 208 is used for routing. It is noted that portions of the shielding layer 208 may also be used to connect components in the encapsulation layer 204. For example, portions of the shielding layer 208 may be configured to provide an electrical connection between the first component 210 and the second component 212. Another advantage of this approach is that such a connection may bypass the substrate 202. The connection may go through a backside of the components.

In some implementations, coupling a component (e.g., 210, 212, 214) to a portion of the shielding layer 208 that is coupled to ground is simpler than coupling the component through the substrate. For example, a portion of the shielding layer 208 may be coupled through a backside of one or more components, greatly simplifying the route for ground for the component(s). Thus, the disclosure describes an effective way of providing ground connections for a variety of components. This may avoid providing complicated routing in the substrate 202. By reducing the number of routes in the substrate 202, a thinner substrate 202 may be provided. For examples, in some implementations, routes that would have normally been designed in the substrate 202 has been designed as part of the shielding layer 208.

In some implementations, a portion of the shielding layer 208 may be coupled (e.g., directly coupled) to one or more interconnects of the substrate 202, through the side of the substrate 202. For example, a portion of the shielding layer 208 may be coupled to a ground shield layer of the substrate 202, through interconnects of the substrate 202. The figures of the present disclosure may illustrate that the shielding layer 208 is touching from the side, interconnects of the substrate 202. However, in some implementations, the shielding layer 208 may not be touching from the side, any of the interconnects of the substrate 202. In some implementations, the shielding layer 208 may touching from the side, some of the interconnects of the substrate 202.

### Shielding Layer Structure for Absorbing and Scattering Electromagnetic (EM) Waves

In some implementations, the formation of cavities and the shielding layer over the cavities may create internal surfaces and/or regions for absorbing and/or scattering EM waves. In some implementations, some or all portions of the shielding layer 208 may be means for scattering EM waves.

FIG. 2 illustrates that the encapsulation layer 204 includes exemplary regions A that are defined by portions of the shielding layer 208. The surfaces of the regions A include portions of the shielding layer 208. These surfaces are configured to absorb and/or scatter EM waves emanating from the components in the encapsulation layer 204. By absorbing and/or scattering the EM waves, the surfaces may reduce the effect of the EM waves on other components in the device 200. It is noted that parts of the shielding layer 208 may form or define internal walls that may be configured for absorbing and/or scattering EM waves and/or for providing compartmental and/or conformal shielding. The disclosure describes a way of increasing the surface area for absorbing and/or scattering EM waves without increasing the overall size of the device. In particular, the disclosure describes a way to substantial increase the surface area that is capable of absorbing and/or scattering EM waves, without substantially increasing the overall volume of the device.

In view of the above, the shielding layer 208 may provide multi-function capabilities for a device (e.g., 200). For example, one or more portions of the shielding layer 208 may be configured to provide (i) EM shielding for one or more components, (ii) heat dissipating capabilities for components of the device 200, (iii) connections between components and the substrate, and/or (iv) surfaces and space for absorbing and/or scattering EM waves. In some implementations, one or more portions may provide more than one functionality. For example, a portion of the shielding layer 208 may provide EM conformal and compartmental shielding. In another example, a portion of the shielding layer 208 may provide EM shielding and heat dissipation. In another example, a portion of the shielding layer 208 may provide heat dissipation and electrical connection. In another example, a portion of the shielding layer 208 may provide EM shielding and electrical connection.

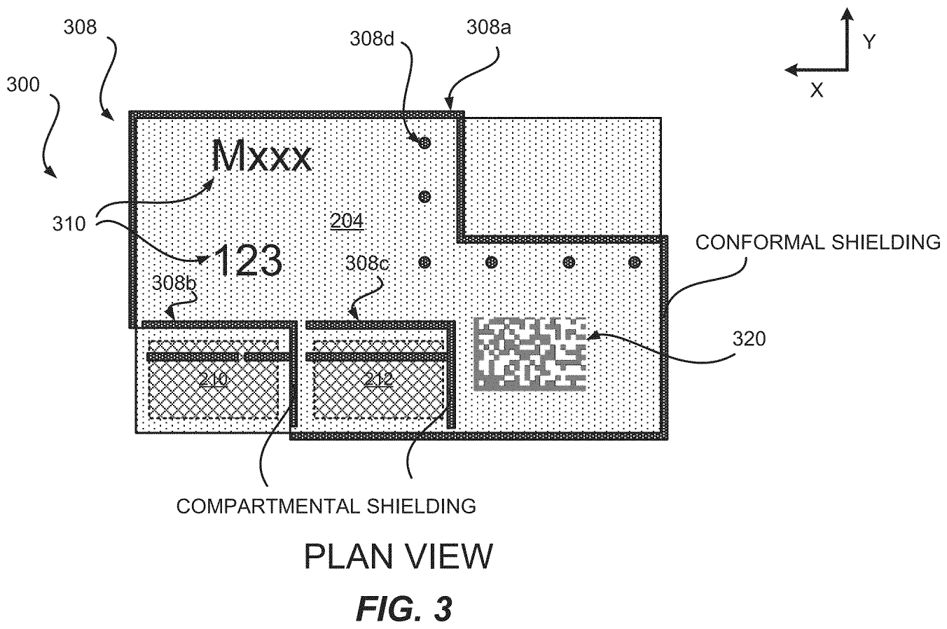

FIG. 3 illustrates a plan view of a device 300 that includes a substrate, several components, an encapsulation layer 204, and a shielding layer 308. The device 300 may be similar to the device 200 of FIG. 2. The shielding layer 308 includes a first portion 308a of the shielding layer 308, a second portion 308b of the shielding layer 308, a third portion 308c of the shielding layer 308, and a fourth portion 308d of the shielding layer 308. In some implementations, the first portion 308a of the shielding layer 308 is configured to provide conformal and compartmental EM shielding. The first portion 308a of the shielding layer 308 may be formed over and/or around the encapsulation layer 204 and/or the substrate. In some implementations, the second portion 308b of the shielding layer 308 is configured to provide EM shielding and heat dissipation for the first component 210. In some implementations, the third portion 308c of the shielding layer 308 is configured to provide EM shielding and an electrical connection for the second component 212. In some implementations, the fourth portion 308d of the shielding layer 308 is configured to provide a Faraday cage, to improve EM shielding.

In some implementations, labeling can be created in the encapsulation layer 204 and/or the shielding layer 308. For example, a labeling 310 may be formed in the encapsulation layer 204. Similarly, the labeling 310 may be formed in the shielding layer 308. In some implementations, the labeling 310 may be formed in the encapsulation layer 204 and the shielding layer 308. The labeling 310 may be formed by using a laser etching process. In some implementations, a labeling 320 that can be used as a barcode (e.g., QR code) is formed in the encapsulation layer 204. It is noted that labeling 310 may also act or be configured to provide EM scattering and/or heat dissipation.

FIG. 2 illustrates one example of a device that includes a shielding layer with compartmental shielding where there are gaps and spaces in the compartmental EM shield. However, different portions of the shielding layer 208 may fill cavities of the encapsulation layer 204 differently.

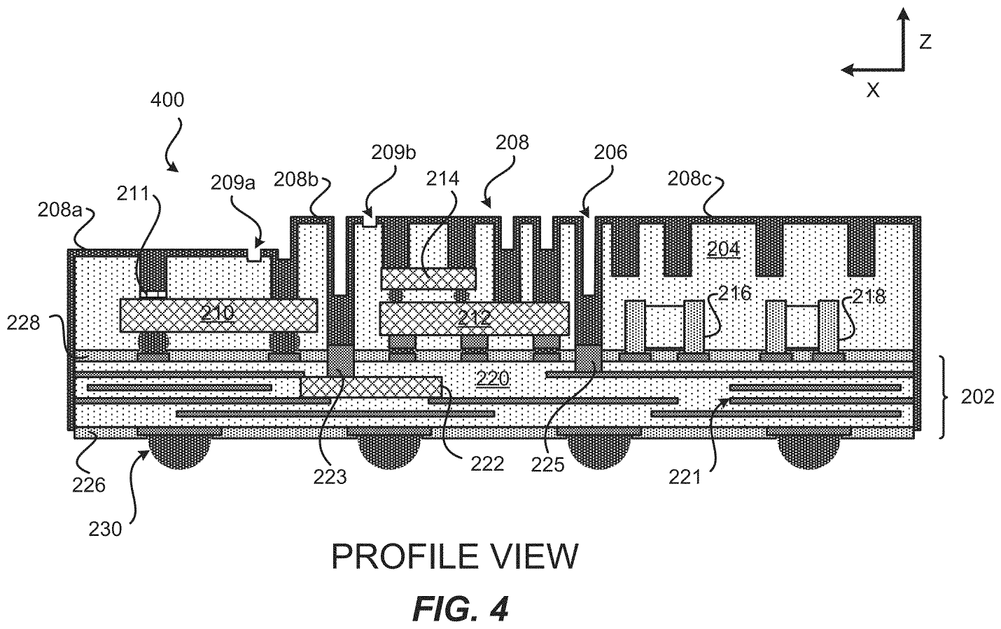

FIG. 4 illustrates a device 400 that includes the shielding layer 208. The device 400 is similar to the device 200. FIG. 4 illustrates that the shielding layer 208 includes portions that fill cavities in the encapsulation layer 204 differently. In some implementations, cavities of the encapsulation layer 204 may be partially filled and/or completely filled.

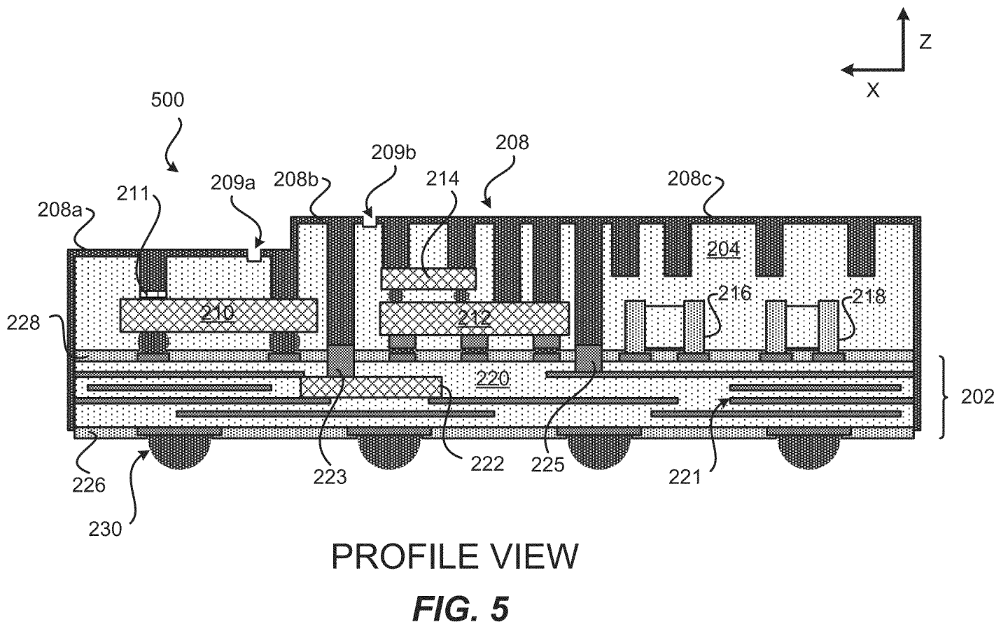

FIG. 5 illustrates a device 500 that includes the shielding layer 208. The device 500 is similar to the device 200. FIG. 5 illustrates that the shielding layer 208 includes portions that fill cavities in the encapsulation layer 204 differently. In some implementations, cavities of the encapsulation layer 204 may be completely filled.

Having described various implementations of a device that includes a shielding layer. A sequence for fabricating a device that includes a shielding layer will be further described below.

### Exemplary Sequence for Fabricating a Device Comprising Compartmental Electromagnetic (EM) Shield

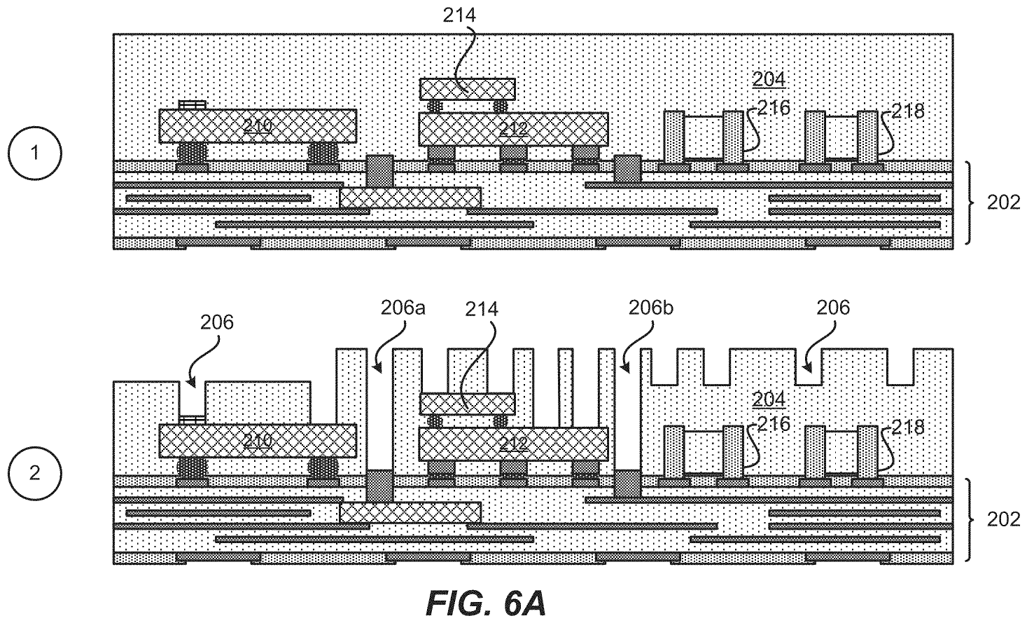

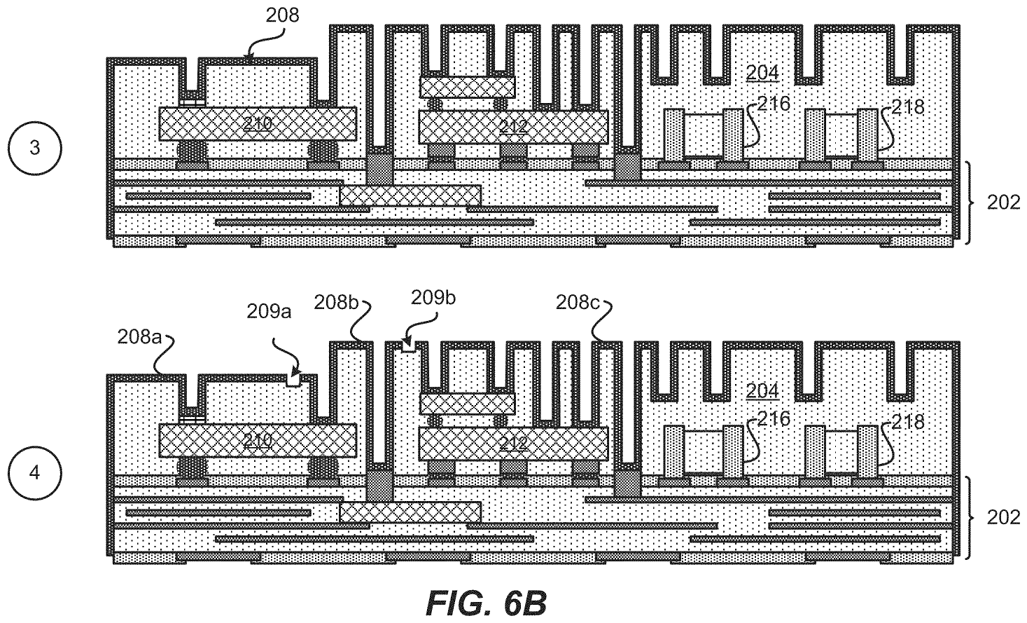

FIG. 6 (which includes FIGS. 6A-6B) illustrates an exemplary sequence for providing or fabricating a device that includes a shielding layer. In some implementations, the sequence of FIGS. 6A-6B may be used to provide or fabricate the device 200 of FIG. 2, or any of the devices described in the present disclosure.

It should be noted that the sequence of FIGS. 6A-6B may combine one or more stages in order to simplify and/or clarify the sequence for providing or fabricating the device. In some implementations, the order of the processes may be changed or modified. In some implementations, one or more of processes may be replaced or substituted without departing from the spirit of the disclosure. In some implementations, the process may be performed after a dicing process that singulates a wafer into several individual devices.

Stage 1, as shown in FIG. 6A, illustrates a state after a device 200 is provided. The device 200 includes the substrate 202, components (e.g., 210, 212, 214, 216, 218), and an encapsulation layer 204. Different implementations may provide the encapsulation layer 204 over the substrate 202 and the components, by using various processes. For example, the encapsulation layer 204 may be provided over the substrate 202 and the components, by using a compression and transfer molding process, a sheet molding process, or a liquid molding process.

Stage 2 illustrates a state after a plurality of cavities 206 (e.g., 206a, 206b) is formed over the encapsulation layer 204. Different implementations may form the plurality of cavities 206 differently in the encapsulation layer 204. Stage 2 illustrates that a portion of the encapsulation layer 204 over the first component 210 has been removed. Different implementations may use different processes for forming the plurality of cavities 206 and/or removing portions of the encapsulation layer 204. In some implementations, a laser process (e.g., laser ablation) may be use to form the plurality of cavities 206 in the encapsulation layer 204. In some implementations, a photo etching process (e.g., photo-lithography process) may be used to form the plurality of cavities 206 and/or remove portions of the encapsulation layer. The plurality of cavities 206 may have walls that are approximately vertical or tapered (e.g., angled, non-vertical, diagonal).

Stage 3, as shown in FIG. 6B, illustrates a state after a shielding layer 208 is formed over the encapsulation layer 204. Forming the shielding layer 208 may include forming the shielding layer 208 (i) over cavities of the encapsulation layer, (ii) over a horizontal surface of the encapsulation layer 204 and/or (iii) over a vertical surface (e.g., side surface, lateral surface) of the encapsulation layer 204 and/or the substrate 202. One or more portions of the shielding layer 208 may be configured to couple to ground. The shielding layer 208 may include one or more layers. The shielding layer 208 may include one or more metal layers and/or one or more non-metal layers. Examples of materials for the shielding layer 208 are described above. Different implementations may form the shielding layer 208 differently in the cavities 206. In some implementations, one or more of the cavities 206 may be partially filled and/or completely filled. Different implementations may use different processes for forming the shielding layer 208. In some implementations, a chemical vapor deposition (CVD) process and/or a physical vapor deposition (PVD) process for forming the shielding layer. For example, a sputtering process, a spray coating, and/or a plating process may be used to form the shielding layer 208.

Stage 4 illustrates a state after the shielding layer 208 is patterned and/or separated into several portions. An etching process (e.g., photo-etching process) and/or a laser ablation process may be used to form breaks 209a and/or 209b in the shielding layer 208. It is noted that the etching process and/or the laser ablation process may remove larger portions of the shielding layer 208 and/or encapsulation layer 204.

FIGS. 6A-6B illustrate an example of a sequence for fabricating a device that includes EM shielding. Different implementations may use a different process and/or a sequence.

### Exemplary Flow Diagram of a Method for Fabricating a Device Comprising Compartmental Electromagnetic (EM) Shield

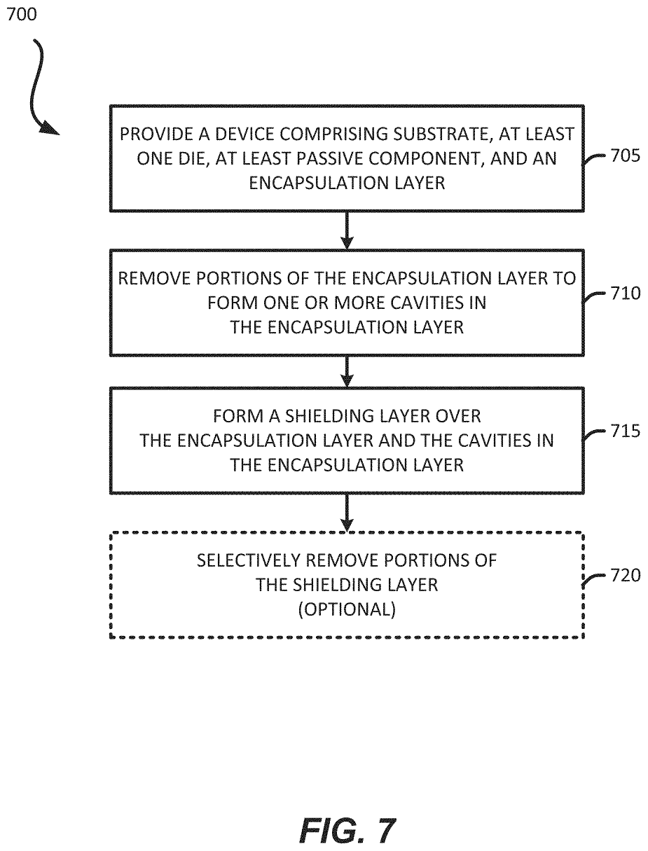

In some implementations, fabricating a device that includes a shielding layer includes several processes. FIG. 7 illustrates an exemplary flow diagram of a method 700 for providing or fabricating a device that includes a shielding layer. In some implementations, the method 700 of FIG. 7 may be used to provide or fabricate the device of FIG. 2 described in the disclosure. However, the method 700 may be used to provide or fabricate any of the devices (e.g., 200, 400, 500, 800, 900, 1000) described in the disclosure.

It should be noted that the sequence of FIG. 7 may combine one or more processes in order to simplify and/or clarify the method for providing or fabricating a device. In some implementations, the order of the processes may be changed or modified.

The method provides (at 705) a device (e.g., 200) includes a substrate (e.g., 202), components (e.g., 210, 212, 214, 216, 218), and an encapsulation layer (e.g., 204). Different implementations may provide the encapsulation layer over the substrate and the components by using various processes. For example, the encapsulation layer may be provided over the substrate and the components by using a compression and transfer molding process, a sheet molding process, or a liquid molding process. Stage 1 of FIG. 6A illustrates an example of providing a device that includes an encapsulation.

The method removes (at 710) portions of the encapsulation layer to form cavities (e.g., 206) in the encapsulation layer. Different implementations may form the plurality of cavities differently in the encapsulation layer. In some implementations, a laser process (e.g., laser ablation) may be use to form the plurality of cavities in the encapsulation layer. In some implementations, a photo etching process (e.g., photo-lithography process) may be used to form the plurality of cavities and/or remove portions of the encapsulation layer. The plurality of cavities in the encapsulation layer may have walls that are approximately vertical or tapered (e.g., angled, non-vertical, diagonal). Stage 2 of FIG. 6A illustrates an example of forming a plurality of cavities in the encapsulation layer.

The method forms (at 715) a shielding layer (e.g., 208) over the encapsulation layer and/or the substrate. In some implementations, forming a shielding layer may include forming a shielding layer (i) over cavities of the encapsulation layer, (ii) over a horizontal surface of the encapsulation layer and/or (iii) over a vertical surface (e.g., side surface, lateral surface) of the encapsulation layer and/or the substrate. One or more portions of the shielding layer 208 may be configured to couple to ground. The shielding layer 208 may include one or more layers. The shielding layer may include one or more metal layers and/or one or more non-metal layers. Examples of materials for the shielding layer is described above.

Different implementations may form the shielding layer differently in the cavities. In some implementations, one or more of the cavities may be partially filled and/or completely filled. Different implementations may use different processes for forming the shielding layer. In some implementations, a chemical vapor deposition (CVD) process and/or a physical vapor deposition (PVD) process for forming the shielding layer. For example, a sputtering process, a spray coating, and/or a plating process may be used to form the shielding layer. Stage 3 of FIG. 6B illustrates an example of forming a shielding layer.

The method optionally removes (at 720) portions of the shielding layer 208 to separate the shielding layer 208 into different portions. An etching process (e.g., photo-etching process) and/or a laser ablation process may be used to form breaks 209a and/or 209b in the shielding layer 208 that separate the shielding layer 208. It is noted that the etching process and/or the laser ablation process may remove larger portions of the shielding layer and/or encapsulation layer. Stage 4 of FIG. 6B illustrates an example of the shielding layer 208 being separated into different portions.

The method 700 of FIG. 7 may be applicable to any of the devices described in the disclosure, including the devices 200, 400, 500, 800, 900 and/or 1000.

### Exemplary Devices Comprising Compartmental Electromagnetic (EM) Shield

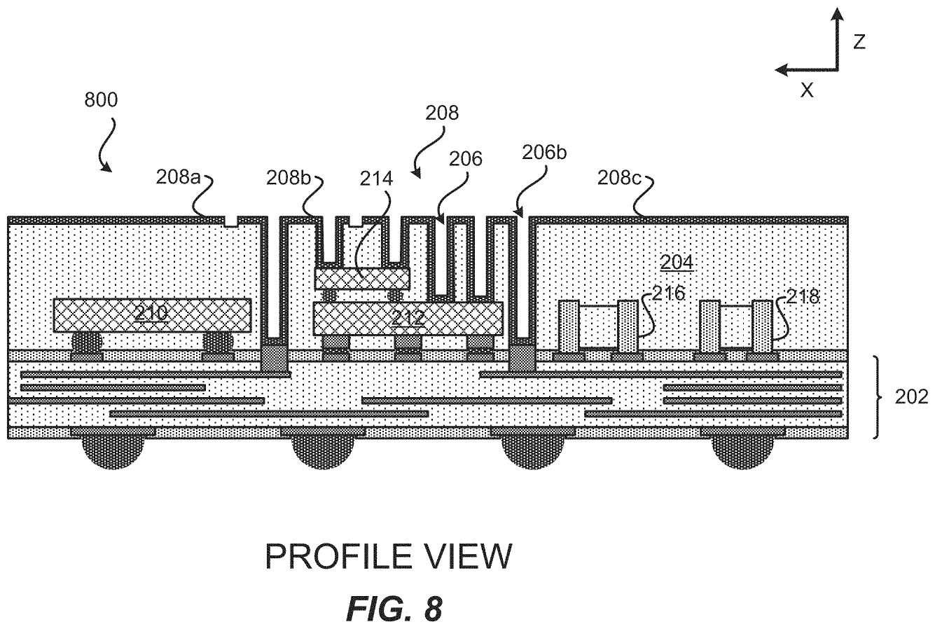

As mentioned above, a device with electromagnetic (EM) shielding may have different arrangements, configurations and/or structure. FIG. 8 illustrates a profile view of a device 800 that includes a shielding layer 208. The device 800 is similar to the device 200. FIG. 8 illustrates the shielding layer 208 is located (i) over horizontal portion of the encapsulation layer 204, and (ii) in the cavities 206 of the encapsulation layer 204. However, there is no shielding layer 208 on a side portion of the encapsulation layer 204 or a side portion of the substrate 202. Thus, instead of full EM shielding of the device 800, the shielding layer 208 provides partial EM shielding of the device 800. In FIG. 8, it may be that the second component 212 may need shielding and/or isolation from other components. However, shielding the other components of the device 800 is not as important and/or does not result in meaningful performance gains. The second component 212 has conformal shielding and compartmental shielding, while the first component 210 only has partial conformal shielding from external EM waves.

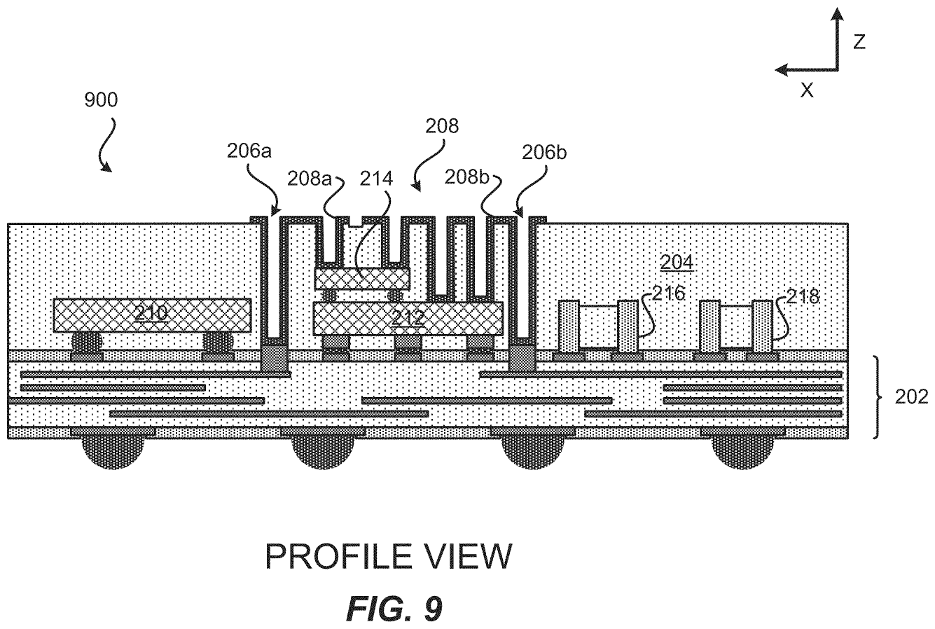

FIG. 9 illustrates a profile view of a device 900 that includes a shielding layer 208. The device 900 is similar to the device 800. FIG. 9 illustrates that the second component 212 and the third component 214 have conformal and compartmental shielding, while the first component 210 does not have conformal shielding, leaving the first component 210 exposed to external EM waves.

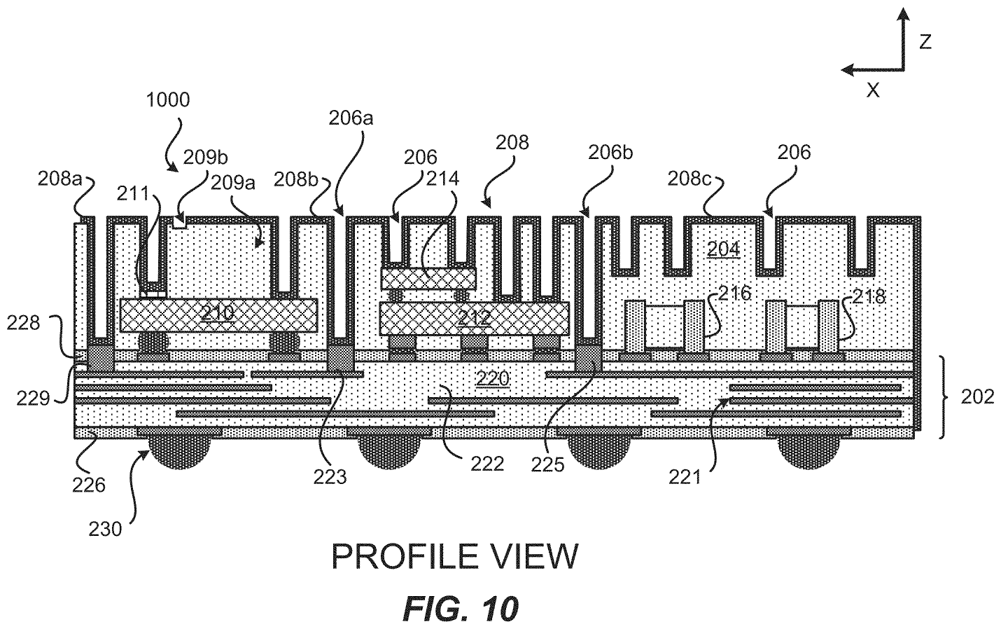

FIG. 10 illustrates a device 100 that includes a shielding layer 208. The device 1000 is similar to the device 200. FIG. 10 illustrates that the portions (e.g., side portion) of the encapsulation layer 204 is not covered by the shielding layer 208. In addition, the first portion 208a of the shielding layer 208 is configured as an interconnect that couples the first component 210 to the substrate 202 through the heat sink 211 and the interconnect 229. In some implementations, the first portion 208a of the shielding layer 208 is coupled to a backside portion of the first component 210.

### Exemplary Sequence for Fabricating a Device Comprising Compartmental Electromagnetic (EM) Shield

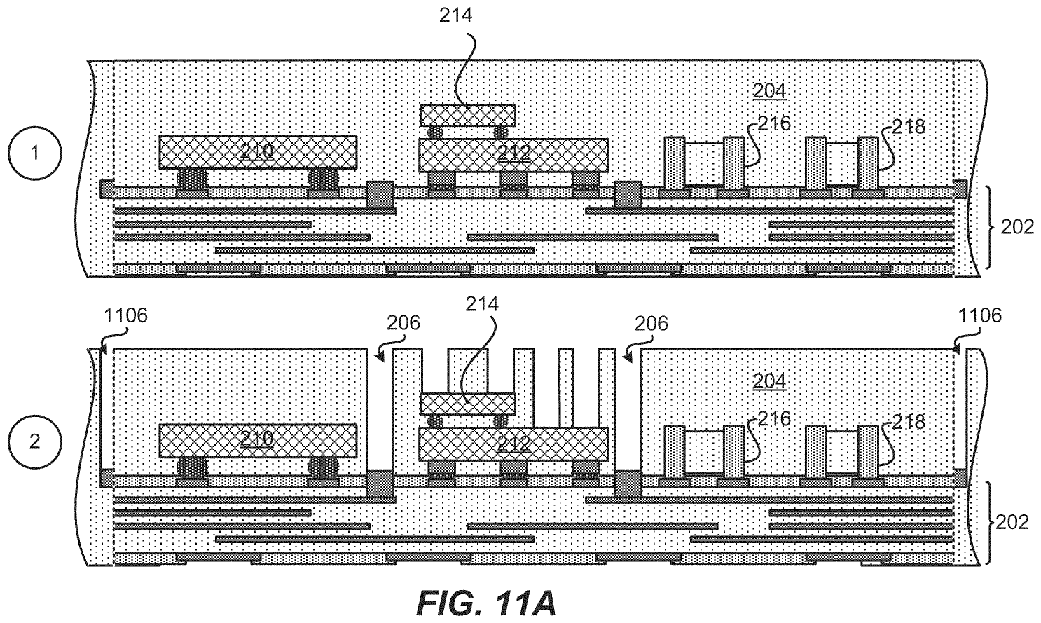

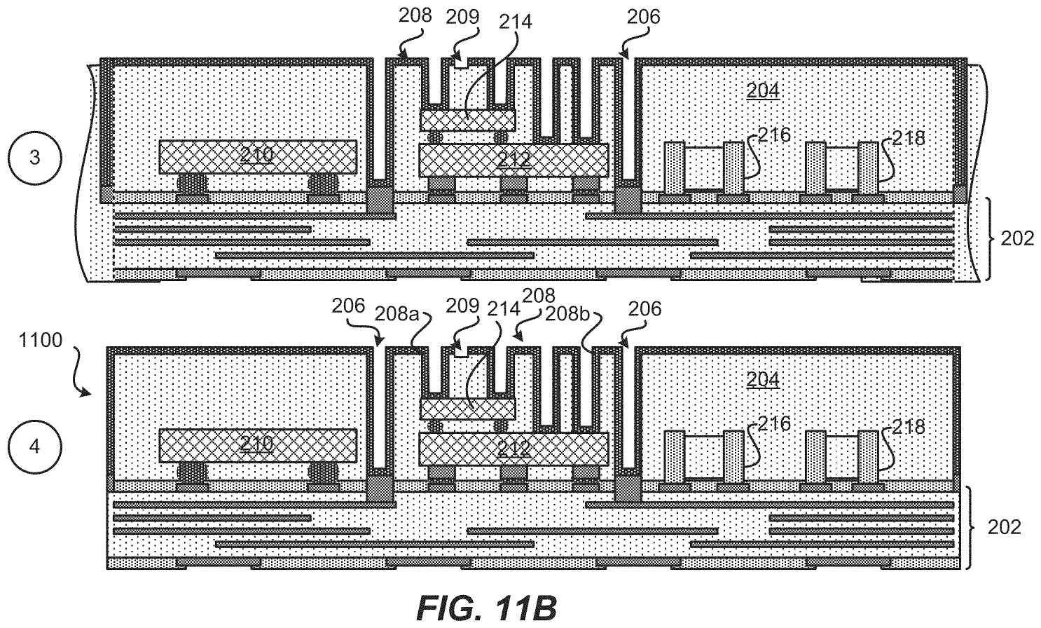

FIG. 11 (which includes FIGS. 11A-11B) illustrates an exemplary sequence for providing or fabricating a device that includes a shielding layer. The sequence of FIGS. 11A-11B may be used to provide or fabricate any of the devices described in the present. FIGS. 11A-11B illustrate a process when the process of forming the shielding layer may be performed before a singulation process.

It should be noted that the sequence of FIGS. 11A-11B may combine one or more stages in order to simplify and/or clarify the sequence for providing or fabricating the device. In some implementations, the order of the processes may be changed or modified. In some implementations, one or more of processes may be replaced or substituted without departing from the spirit of the disclosure.

Stage 1, as shown in FIG. 11A, illustrates a state after a wafer that includes several devices is provided. The wafer may include the substrate 202, components (e.g., 210, 212, 214, 216, 218), and an encapsulation layer 204. Different implementations may provide the encapsulation layer 204 over the substrate 202 and the components by using various processes. For example, the encapsulation layer 204 may be provided over the substrate 202 and the components by using a compression and transfer molding process, a sheet molding process, or a liquid molding process.

Stage 2 illustrates a state after a plurality of cavities 206 and 1106 are formed over the encapsulation layer 204. Different implementations may form the plurality of cavities 206 differently in the encapsulation layer 204. Stage 2 illustrates that a portion of the encapsulation layer 204 over the first component 210 has been removed. Different implementations may use different processes for forming the plurality of cavities 206 and/or removing portions of the encapsulation layer 204. In some implementations, a laser process (e.g., laser ablation) may be use to form the plurality of cavities 206 in the encapsulation layer 204. In some implementations, a photo etching process (e.g., photo-lithography process) may be used to form the plurality of cavities 206 and/or remove portions of the encapsulation layer. The plurality of cavities 206 may have walls that are approximately vertical or tapered (e.g., angled, non-vertical, diagonal). In some implementations, the plurality of cavities 1106 may be near or along scribe lines that separates the different devices of the wafer. The scribe lines are portions of the wafer that are diced during singulation of the wafer.

Stage 3, as shown in FIG. 11B, illustrates a state after a shielding layer 208 is formed over the encapsulation layer 204. Forming the shielding layer 208 may include forming the shielding layer 208 (i) over cavities (e.g., 206, 1106) of the encapsulation layer, (ii) over a horizontal surface of the encapsulation layer 204 and/or (iii) over a vertical surface (e.g., side surface, lateral surface) of the encapsulation layer 204 and/or the substrate 202. One or more portions of the shielding layer 208 may be configured to couple to ground. The shielding layer 208 may include one or more layers. The shielding layer 208 may include one or more metal layers and/or one or more non-metal layers. Examples of materials for the shielding layer 208 are described above. Different implementations may form the shielding layer 208 differently in the cavities 206 and 1106. In some implementations, one or more of the cavities 206 and 1106 may be partially filled and/or completely filled. Different implementations may use different processes for forming the shielding layer 208. In some implementations, a chemical vapor deposition (CVD) process and/or a physical vapor deposition (PVD) process for forming the shielding layer. For example, a sputtering process, a spray coating, and/or a plating process may be used to form the shielding layer 208. The shielding layer 208 may be patterned and/or separated into several portions. An etching process (e.g., photo-etching process) and/or a laser ablation process may be used to form breaks 209a and/or 209b in the shielding layer 208.

Stage 4 illustrates a state after the wafer is singulated into a plurality of devices 1100. A mechanical process (e.g., saw) may be used to singulate the wafer into individual devices 1100. Each of the device 1100 may include a substrate 202, components, an encapsulation layer and a shielding layer 208.

FIGS. 11A-11B illustrate an example of a sequence for fabricating a device that includes EM shielding, where at least some of the shielding layer is formed before a singulation process. Different implementations may use a different process and/or sequence.

### Exemplary Electronic Devices

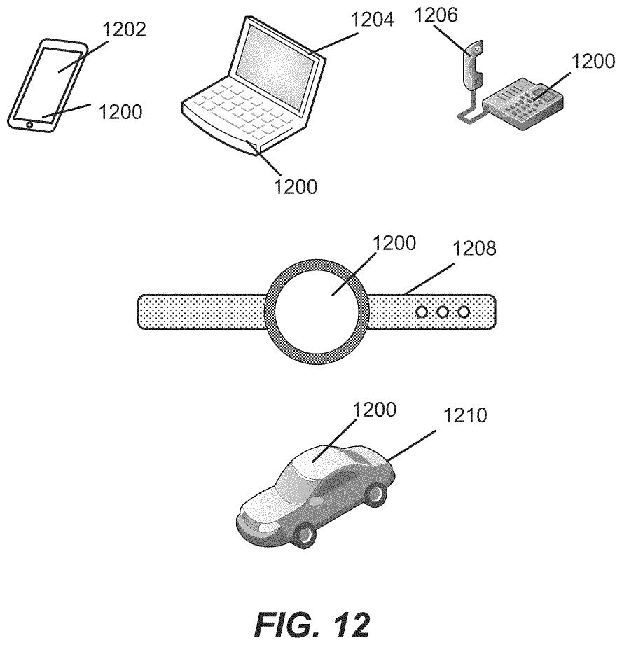

FIG. 12 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1202, a laptop computer device 1204, a fixed location terminal device 1206, a wearable device 1208, or automotive vehicle 1210 may include a device 1200 as described herein. The device 1200 may be, for example, any of the devices and/or integrated circuit (IC) packages described herein. The devices 1202, 1204, 1206 and 1208 and the vehicle 1210 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 2-5, 6A-6B, 7-9, 10, 11A-11B, and/or 12 may be rearranged and/or combined into a single component, process, feature or function or embodied in several components, processes, or functions. Additional elements, components, processes, and/or functions may also be added without departing from the disclosure. It should also be noted FIGS. FIGS. 2-5, 6A-6B, 7-9, 10, 11A-11B, and/or 12 and its corresponding description in the present disclosure is not limited to dies and/or ICs. In some implementations, FIGS. 2-5, 6A-6B, 7-9, 10, 11A-11B, and/or 12 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. The term “about ‘value X’”, or “approximately value X”, as used in the disclosure shall mean within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that may be configured to provide an electrical path for a signal (e.g., a data signal, ground or power). An interconnect may be part of a circuit. An interconnect may include more than one element or component.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a substrate;
a first component coupled to the substrate;
a second component coupled to the substrate;
an encapsulation layer formed over the substrate such that the encapsulation layer encapsulates the first component and the second component; and
a shielding layer formed over a first surface of the encapsulation layer,
wherein the shielding layer includes a first portion formed in a first cavity of the encapsulation layer,
wherein the first cavity is located between the first component and the second component, and
wherein the first portion of the shielding layer provides a compartmental electromagnetic (EM) shield between the first component and the second component.

2. The device of claim 1, wherein the first portion of the shielding layer is configured to be coupled to ground.

3. The device of claim 1,
wherein the shielding layer includes a second portion that is coupled to the first component and the substrate, and
wherein the second portion of the shielding layer is an interconnect configured to provide an electrical path between the first component and the substrate.

4. The device of claim 3, wherein a backside of the first component is coupled to the substrate through the second portion of the shielding layer.

5. The device of claim 1, further comprising a third component embedded in the substrate,
wherein the shielding layer includes a second portion that is coupled to the first component and the substrate, and
wherein the second portion of the shielding layer is an interconnect configured to provide an electrical path between the first component and the third component embedded in the substrate.

6. The device of claim 1, wherein the first portion of the shielding layer is formed over a lateral surface of the encapsulation layer such the first portion provides a conformal EM shield for the second component.

7. The device of claim 1,
wherein the shielding layer includes a second portion that is coupled to the first component, and
wherein the second portion is configured to provide heat dissipation of the first component.

8. The device of claim 1, wherein a spacing between the first component and the first portion of the shielding layer that provides the compartmental electromagnetic (EM) shield is approximately less than 75 micrometers (μm).

9. The device of claim 1, wherein the first portion of the shielding layer is formed in the first cavity such that the first cavity is partially filled.

10. The device of claim 1, wherein the first portion of the shielding layer is formed in the first cavity such that the first cavity is completely filled.

11. The device of claim 1,
wherein the encapsulation layer includes a plurality of cavities that are covered with the shielding layer, and
wherein the plurality of cavities covered with the shielding layer form internal walls that are configured to scatter EM waves from the first component.

12. The device of claim 1, wherein the first component includes an electronic component, a radio frequency (RF) component, a die, or a passive component.

13. The device of claim 1, wherein the shielding layer includes a second portion formed over a side portion of the encapsulation layer.

14. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

15. A device comprising:
a substrate;
a first component coupled to the substrate;
a second component coupled to the substrate;
means for encapsulating formed over the substrate such that the means for encapsulating encapsulates the first component and the second component; and
means for shielding formed over a first surface of the means for encapsulating,
wherein the means for shielding includes a first portion formed in a first cavity of the means for encapsulating,
wherein the first cavity is located between the first component and the second component, and
wherein the first portion of the means for shielding provides means for compartmental electromagnetic (EM) shielding between the first component and the second component.

16. The device of claim 15, wherein the first portion of the means for shielding is configured to be coupled to ground.

17. The device of claim 15,
wherein the means for shielding includes a second portion that is coupled to the first component and the substrate, and
wherein the second portion of the means for shielding is an interconnect configured to provide an electrical path between the first component and the substrate.

18. The device of claim 17, wherein a backside of the first component is coupled to the substrate through the second portion of the means for shielding.

19. The device of claim 15, further comprising a third component embedded in the substrate,
wherein the means for shielding includes a second portion that is coupled to the first component and the substrate, and
wherein the second portion of the means for shielding is an interconnect configured to provide an electrical path between the first component and the third component embedded in the substrate.

20. The device of claim 15, wherein the first portion of the means for shielding is formed over a lateral surface of the means for encapsulating such the first portion provides means for conformal EM shielding for the second component.

21. The device of claim 15,
wherein the means for shielding includes a second portion that is coupled to the first component, and
wherein the second portion is configured to provide means for heat dissipating of the first component.

22. The device of claim 15,
wherein the means for encapsulating includes a plurality of cavities that are covered with the means for shielding, and
wherein the plurality of cavities covered with the means for shielding form means for scattering EM waves.

23. A method for fabricating a device having shielding, comprising:
providing a device that includes:
a substrate;
a first component coupled to the substrate;
a second component coupled to the substrate; and
an encapsulation layer formed over the substrate such that the encapsulation layer encapsulates the first component and the second component;
forming a plurality of cavities in the encapsulation layer, including forming a first cavity in the encapsulation layer between the first component and the second component; and
forming a shielding layer over a first surface of the encapsulation layer, including forming a first portion of the shielding layer in the first cavity of the encapsulation layer, wherein the first portion of the shielding layer provides a compartmental electromagnetic (EM) shield between the first component and the second component.

24. The method of claim 23, wherein the first portion of the shielding layer is configured to be coupled to ground.

25. The method of claim 23,
wherein forming the shielding layer includes forming a second portion of the shielding layer such that the second portion is coupled to the first component and the substrate, and
wherein the second portion of the shielding layer is an interconnect configured to provide an electrical path between the first component and the substrate.

26. The method of claim 23,
wherein the device includes a third component embedded in the substrate,
wherein forming the shielding layer includes forming a second portion of the shielding layer such that the second portion that is coupled to the first component and the substrate, and
wherein the second portion of the shielding layer is an interconnect configured to provide an electrical path between the first component and the third component embedded in the substrate.

27. The method of claim 23,
wherein forming the shielding layer includes forming a second portion of the shielding layer such that the second portion is coupled to the first component, and
wherein the second portion is configured to provide heat dissipation of the first component.

28. The method of claim 23, wherein the first portion of the shielding layer is formed in the first cavity such that the first cavity is partially filled.

29. The method of claim 23, wherein the first portion of the shielding layer is formed in the first cavity such that the first cavity is completely filled.
